(19) United States
(12) Patent Application Publication
(10) Pub. No.: US 2021/0336179 A1
(43) Pub. Date: Oct. 28, 2021

(54) DISPLAY PANEL AND MANUFACTURING METHOD THEREOF AND DISPLAY DEVICE

(71) Applicant: WUHAN CHINA STAR OPOELECTRONICS SEMICONDUCTOR DISLPAY TECHNOLOGY CO., LTD., Wuhan, Hubei (CN)

(72) Inventor: Yamei BAI, Wuhan, Hubei (CN)

(21) Appl. No.: 16/494,405

(22) PCT Filed: May 15, 2019
(86) PCT No.: PCT/CN2019/086944

§ 371 Date: Sep. 16, 2019

(30) Foreign Application Priority Data
Apr. 28, 2019 (CN) 201910351430.0

(51) Int. Cl. H01L 51/50; H01L 51/56

(52) U.S. Cl. CPC H01L 51/5096; H01L 51/5056; H01L 51/5072; H01L 51/56; H01L 51/5092

(57) ABSTRACT

A display panel, a method of manufacturing the display panel, and a display device include a substrate, and a pixel separate layer and an organic light-emitting device layer both sequentially disposed on the substrate. The pixel separate layer includes a plurality of dividing bodies and a plurality of open areas spaced apart from each other. Adjacent two of the open areas are separated by the dividing bodies. The organic light-emitting device layer includes a plurality of organic light-emitting devices each including a hole injection layer, and the hole injection layers of adjacent two of the organic light-emitting devices are spaced apart from each other.

### BACKGROUND OF INVENTION

### 1. Field of Invention

The present invention relates to a display field, and particularly, to a display panel, a manufacturing method thereof, and a display device.

### 2. Related Art

Organic light-emitting diode (OLED) devices have become the most promising novel display devices in recent years due to advantages of being self-luminous, being solid state, and high contrast.

However, there is charge crosstalk of luminous effects in OLED devices that adversely affects luminous efficiency and lifespans of the OLED devices. Therefore, how to prevent charge crosstalk of luminous effects from occurring in OLED devices has become one of the most urgent difficulties to be solved now.

### SUMMARY OF INVENTION

An object of the present application is to provide a display panel, a manufacturing method thereof, and a display device to effectively prevent charge crosstalk of luminous effects from occurring in a light-emitting device, thereby to improve luminous efficiency of the light-emitting device and to extend service life thereof.

To overcome the above-mentioned problem, the embodiment of the present application provides a display panel, comprising a substrate, and a pixel separate layer and an organic light-emitting device layer both sequentially disposed on the substrate; wherein the pixel separate layer comprises a plurality of dividing bodies and a plurality of open areas spaced apart from each other, wherein adjacent two of the open areas are separated by the dividing bodies, and the organic light-emitting device layer comprises a plurality of organic light-emitting devices each comprising a hole injection layer, and wherein the hole injection layers of adjacent two of the organic light-emitting devices are spaced apart from each other.

In one aspect, each of the organic light-emitting devices further comprises a hole transport layer disposed on the pixel separate layer configured with the hole injection layer, wherein the hole transport layers of adjacent two of the organic light-emitting devices are spaced apart from each other.

In one aspect, each of the organic light-emitting devices further comprises a light-emitting layer disposed on the pixel separate layer configured with the hole injection layer, wherein the light-emitting layers of adjacent two of the organic light-emitting devices are spaced apart from each other.

In one aspect, each of the organic light-emitting devices further comprises an electron transport layer disposed on the pixel separate layer configured with the hole injection layer, wherein the electron transport layers of adjacent two of the organic light-emitting devices are spaced apart from each other.

In one aspect, each of the organic light-emitting devices further comprises an electron blocking layer, a hole blocking layer, and an electron injection layer sequentially disposed away from the hole injection layer, wherein at least one of the electron blocking layers, the hole blocking layers, and the electron injection layers of adjacent two of the organic light-emitting devices are spaced apart from each other.

In one aspect, each of the organic light-emitting devices further comprises an anode disposed on the open area and located between the substrate and the hole injection layer.

To overcome the above-mentioned problem, the embodiment of the present application further provides a method of manufacturing a display panel, comprising providing a substrate; forming a pixel separate layer comprising a plurality of dividing bodies and a plurality of open areas spaced apart from each other, wherein adjacent two of the open areas are separated by the dividing bodies; and forming an organic light-emitting device layer on the substrate configured with the pixel separate layer, wherein the organic light-emitting device layer comprises a plurality of organic light-emitting devices each comprising a hole injection layer, and wherein the hole injection layers of adjacent two of the organic light-emitting devices are spaced apart from each other.

In one aspect, the forming an organic light-emitting device layer on the substrate configured with the pixel separate layer comprises: depositing, by using a first fine mask, a hole injection layer on the substrate configured with the pixel separate layer; and depositing a hole transport layer, a light-emitting layer, and an electron transport layer in sequence on the pixel separate layer configured with the hole injection layer, wherein at least one of the hole transport layer, light-emitting layer, and the electron transport layer is formed by using a second fine mask.

In one aspect, before the depositing, by using a first fine mask, a hole injection layer on the substrate configured with the pixel separate layer, the method further comprises: evaporating an anode in the open areas

In one aspect, the depositing a hole transport layer, a light-emitting layer, and an electron transport layer in sequence on the pixel separate layer configured with the hole injection layer comprises: depositing, by using the second fine mask, the hole transport layer on the pixel separate layer configured with the hole injection layer; depositing, by using an opening mask, the light-emitting layer and the electron transport layer in sequence on the pixel separate layer configured with the hole transport layer.

In one aspect, each of the organic light-emitting devices further comprises an electron blocking layer, a hole blocking layer, and an electron injection layer sequentially disposed away from the hole injection layer, wherein at least one of the electron blocking layers, the hole blocking layers, and the electron injection layers of adjacent two of the organic light-emitting devices are spaced apart from each other.

To overcome the above-mentioned problem, the embodiment of the present application further provides a display device, comprising a driving circuit and a display panel, wherein the driving circuit is configured to provide a driving voltage for the display panel, and the display panel comprises substrate, and a pixel separate layer and an organic light-emitting device layer both sequentially disposed on the substrate; wherein the pixel separate layer comprises a plurality of dividing bodies and a plurality of open areas spaced apart from each other, wherein adjacent two of the open areas are separated by the dividing bodies, and the organic light-emitting device layer comprises a plurality of organic light-emitting devices each comprising a hole injection layer, and wherein the hole injection layers of adjacent two of the organic light-emitting devices are spaced apart from each other.

In one aspect, each of the organic light-emitting devices further comprises a hole transport layer disposed on the pixel separate layer configured with the hole injection layer, wherein the hole transport layers of adjacent two of the organic light-emitting devices are spaced apart from each other.

In one aspect, each of the organic light-emitting devices further comprises a light-emitting layer disposed on the pixel separate layer configured with the hole injection layer, wherein the light-emitting layers of adjacent two of the organic light-emitting devices are spaced apart from each other.

In one aspect, each of the organic light-emitting devices further comprises an electron transport layer disposed on the pixel separate layer configured with the hole injection layer, wherein the electron transport layers of adjacent two of the organic light-emitting devices are spaced apart from each other.

In one aspect, each of the organic light-emitting devices further comprises an electron blocking layer, a hole blocking layer, and an electron injection layer sequentially disposed away from the hole injection layer, wherein at least one of the electron blocking layers, the hole blocking layers, and the electron injection layers of adjacent two of the organic light-emitting devices are spaced apart from each other.

In one aspect, each of the organic light-emitting devices further comprises an anode disposed on the open area and located between the substrate and the hole injection layer.

The present application has advantageous effects as follows: distinct from the prior art, the display panel of the present application is configured to effectively avoid the occurrence of charge crosstalk of luminous effects in a light-emitting device by spacing the hole injection layers of the adjacent organic light-emitting devices, thereby improving luminous efficiency of the light-emitting device and extending service life thereof.

### BRIEF DESCRIPTION OF DRAWINGS

To describe the technical solutions in the embodiments of the present invention, the following briefly introduces the accompanying drawings for describing the embodiments. Apparently, the accompanying drawings in the following description show merely some embodiments of the present invention, and a person skilled in the art may still derive other drawings from these accompanying drawings without creative efforts.

FIG. 1 is a schematic structural view of a display panel of an embodiment of the present application.

FIG. 2 is another schematic structural view of a display panel of an embodiment of the present application.

FIG. 3 is a schematic structural view of a display panel of an embodiment of the present application.

FIG. 4 is a flowchart showing a method of manufacturing a display panel of an embodiment of the present application.

FIG. 5 is a schematic structural view of a display device of an embodiment of the present application.

### DESCRIPTION OF PREFERRED EMBODIMENTS

The present application will be clearly and completely described in the following with reference to the accompanying drawings in the embodiments. Particularly, the embodiments as described are only a part, but not all, of the embodiments of the present application. Based on the embodiments in the present application, all other embodiments obtained by those skilled in the art without creative efforts shall be within the scope of the present application.

Since charge crosstalk of luminous effects in organic light-emitting diode (OLED) devices adversely affects luminous efficiency and lifespans of the OLED devices. Therefore, how to prevent charge crosstalk of luminous effects from occurring in OLED devices has become one of the most urgent difficulties to be solved now. In order to overcome the above-mentioned problem, the present application provides a display panel to effectively prevent charge crosstalk of luminous effects from occurring in a light-emitting device, thereby to improve luminous efficiency of the light-emitting device and to extend service life thereof.

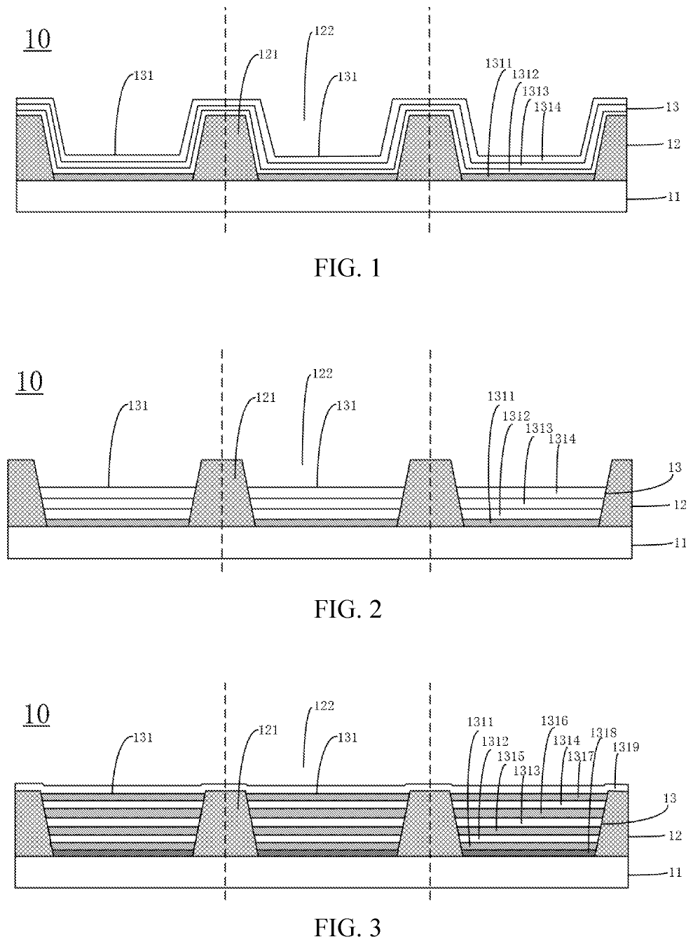

Please refer to FIG. 1. FIG. 1 is a schematic structural view of a display panel of an embodiment of the present application. As shown in FIG. 1, the display panel 10 includes a substrate 11, and a pixel separate layer 12 and an organic light-emitting device layer 13 both sequentially disposed on the substrate 11. The pixel separate layer 12 includes a plurality of dividing bodies 121 and a plurality of open areas 122 spaced apart from each other, wherein adjacent two of the open areas 122 are separated by the dividing bodies 121, and the organic light-emitting device layer 13 includes a plurality of organic light-emitting devices 131. Each of the organic light-emitting devices 131 includes a hole injection layer 1311, wherein the hole injection layers 1311 of adjacent two of the organic light-emitting devices 13 are spaced apart from each other.

The substrate 11 may be a glass substrate or a rigid resin substrate, or may be a flexible substrate for preparing a flexible display panel. The pixel separate layer 12 may be an organic insulating material such as polyimide or epoxy resin, or may be an inorganic insulating material such as silicon nitride (SiNx) or silicon oxide (SiOx). Furthermore, the dividing bodies 121 of the pixel separate layer 12 are configured to define the plurality of open areas 122 spaced apart from each other on the substrate 11. The open areas 122 are formed for setting of the organic light-emitting devices 131. Specifically, part of the organic light-emitting device layer 13 between two dashed lines as shown in FIG. 1 can be defined as one of the organic light-emitting devices 131.

In one embodiment, please continue referring to FIG. 1. Each of the organic light-emitting devices 131 further includes a hole transport layer 1312, a light-emitting layer 1313, and an electron transport layer 1314. The hole transport layer 1312, the light-emitting layer 1313, and the electron transport layer 1314 are sequentially disposed on the pixel separate layer 12 configured with the hole injection layer 1311. The hole transport layers 1312, the light-emitting layers 1313, and the electron transport layers 1314 of the plurality of organic light-emitting devices 131 cooperatively form an entire surface of the hole transport layers 1312, an entire surface of the light-emitting layers 1313, and an entire surface of the electron transport layers 1312, respectively. In this embodiment, the hole injection layers 1311 of adjacent two of the organic light-emitting devices 131 are spaced apart from each other to prevent charge crosstalk of luminous effects from occurring in the hole injection layers 1311 of the organic light-emitting devices 131.

In addition, to prevent charge crosstalk of luminous effects from occurring in the hole transport layers 1312, the light-emitting layers 1313, or the electron transport layers 1314 of the organic light-emitting devices 131, the hole transport layers 1312, the light-emitting layers 1313, or the electron transport layers 1314 of adjacent two of the organic light-emitting devices 131 can also be spaced apart from each other.

For example, as shown in FIG. 2, the hole transport layers 1312 of adjacent two of the organic light-emitting devices 131 are spaced apart from each other to prevent charge crosstalk of luminous effects from occurring in the hole transport layers 1312 of the organic light-emitting devices 131.

As another example, as shown in FIG. 2, the light-emitting layers 1313 of adjacent two of the organic light-emitting devices 131 are spaced apart from each other to prevent charge crosstalk of luminous effects from occurring in the light-emitting layers 1313 of the organic light-emitting devices 131.

As another example, as shown in FIG. 2, the electron transport layers 1314 of adjacent two of the organic light-emitting devices 131 are spaced apart from each other to prevent charge crosstalk of luminous effects from occurring in the electron transport layers 1314 of the organic light-emitting devices 131.

Particularly, in practice, parameters such as efficiency, lifespans, and viewing angles of the hole transport layer, the electron blocking layer, the light-emitting layer, the hole blocking layer, the electron transport layer, and the electron injection layer can be verified to determine whether there are charge crosstalk effects. When there is charge crosstalk of luminous effects, corresponding layers of adjacent two of the organic light-emitting devices 131 can be spaced apart from each other to overcome the problem that the charge crosstalk of luminous effects occur in the corresponding layers.

In a specific embodiment, as shown in FIG. 3, each of the organic light-emitting device 131 further includes an electron blocking layer 1315, a hole blocking layer 1316, and an electron injection layer 1317 sequentially disposed away from the hole injection layer 1311, wherein the electron blocking layer 1315 is disposed between the hole transport layer 1312 and the light-emitting layer 1313, the hole blocking layer 1316 is disposed between the light-emitting layer 1313 and the electron transport layer 1314, and the electron injection layer 1317 covers the electron transport layer 1314. Furthermore, at least one of the electron blocking layers 1315, the hole blocking layers 1316, and the electron injection layers 1317 of adjacent two of the organic light-emitting devices 131 are spaced apart from each other to prevent charge crosstalk of luminous effects from occurring in the electron blocking layers 1315, the hole blocking layers 1316, and the electron injection layers 1317 of the organic light-emitting devices 131.

For example, as shown in FIG. 3, the electron blocking layers 1315 of adjacent two of the organic light-emitting devices 131 are spaced apart from each other to prevent charge crosstalk of luminous effects from occurring in the electron blocking layers 1315 of the organic light-emitting devices 131.

As another example, as shown in FIG. 3, the hole blocking layers 1316 of adjacent two of the organic light-emitting devices 131 are spaced apart from each other to prevent charge crosstalk of luminous effects from occurring in the hole blocking layers 1316 of the organic light-emitting devices 131.

As another example, as shown in FIG. 3, the electron injection layers 1317 of adjacent two of the organic light-emitting devices 131 are spaced apart from each other to prevent charge crosstalk of luminous effects from occurring in the electron injection layers 1317 of the organic light-emitting devices 131.

Particularly, in practice, parameters such as efficiency, lifespans, and viewing angles of the electron blocking layer 1315, the hole blocking layer 1316, and the electron injection layer 1317 can be verified to determine whether there are charge crosstalk effects. When there is charge crosstalk of luminous effects, corresponding layers of adjacent two of the organic light-emitting devices 131 can be spaced apart from each other to overcome the problem that the charge crosstalk of luminous effects occur in the corresponding layers. Furthermore, each of the organic light-emitting devices 131 may include certain layers of the hole injection layer 1311, the hole transport layer 1312, the electron blocking layer 1315, the light-emitting layer 1313, the hole blocking layer 1316, the electron transport layer 1314, and the electron injection layer 1317. For example, each of the organic light-emitting devices 131 may include the hole injection layer 1311, the hole transport layer 1312, the light-emitting layer 1313, and the electron transport layer 1314. Then, based on such a structure, the organic light-emitting device 131 may further include the electron blocking layer 1315, the hole blocking layer 1316, or the electron injection layer 1317.

Further, please continue referring to FIG. 3. The organic light-emitting device 131 further includes an anode 1318 and a cathode 1319. The anode 1318 is disposed on the open area 122 and located between the substrate 11 and the hole injection layer 1311 to effectively avoid charge crosstalk effects occurring in the organic light-emitting device 131. The cathode 1319 is disposed on the pixel separate layer 12 and covers the electron injection layer 1317.

Specifically, the display panel 10 may further include thin-film transistors (not shown) and a planarization layer (not shown) disposed on the substrate 11 in turn, wherein the thin-film transistors are covered with the planarization layer, and the planarization layer is covered with the pixel separate layer 12.

Distinct from the prior art, the display panel in this embodiment is configured to effectively avoid the occurrence of charge crosstalk of luminous effects in a light-emitting device by spacing the hole injection layers of the adjacent organic light-emitting devices, thereby improving luminous efficiency of the light-emitting device and extending service life thereof.

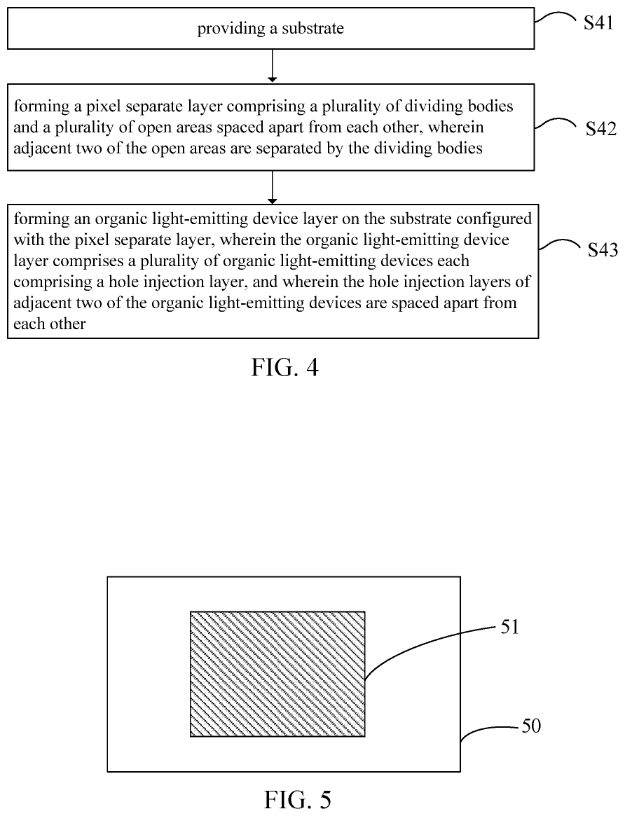

Please refer to FIG. 4. FIG. 4 is a flowchart showing a method of manufacturing a display panel of an embodiment of the present application. The method of manufacturing the display panel includes steps as follows:

S41: providing a substrate. The substrate may be a glass substrate or a rigid resin substrate, or may be a flexible substrate for preparing a flexible display panel.

S42: forming a pixel separate layer including a plurality of dividing bodies and a plurality of open areas spaced apart from each other, wherein adjacent two of the open areas are separated by the dividing bodies.

For example, the pixel separate layer is formed on the substrate by a process such as deposition, exposure, etching, or the like. The separate layer 12 may be an organic insulating material such as polyimide or epoxy resin, or may be an inorganic insulating material such as SiNx or SiOx. Furthermore, the dividing bodies of the pixel separate layer are configured to define the plurality of open areas spaced apart from each other on the substrate. The open areas are formed to define a location where the organic light-emitting devices are disposed.

S43: forming an organic light-emitting device layer on the substrate configured with the pixel separate layer, wherein the organic light-emitting device layer includes a plurality of organic light-emitting devices each including a hole injection layer, and wherein the hole injection layers of adjacent two of the organic light-emitting devices are spaced apart from each other.

In one embodiment, S43 may include a sub step A: depositing a hole injection layer on the substrate configured with the pixel separate layer by using a first fine mask.

For example, align the first fine mask with the open area, and then form a hole injecting layer on the substrate on which the pixel separate layer is formed by vacuum evaporation, physical vapor deposition, chemical vapor deposition, pulsed laser deposition, or the like, so that the hole injection layers of adjacent two of the organic light-emitting devices are spaced apart from each other, thereby preventing charge crosstalk of luminous effects from occurring in the hole injection layers of the organic light-emitting devices.

Specifically, prior to the sub step A, the method further includes: evaporating the anode in the open area. For example, an anode is formed in the open area by vacuum evaporation to enable the anodes of adjacent two of the organic light-emitting devices to be spaced apart, thereby to effectively avoid charge crosstalk effects in the organic light-emitting device 131.

Sub step B: depositing a hole transport layer, a light-emitting layer, and an electron transport layer in sequence on the pixel separate layer configured with the hole injection layer, wherein at least one of the hole transport layer, light-emitting layer, and the electron transport layer is formed by using a second fine mask.

For example, sub step B may specifically include: (1) aligning the second fine mask with the hole injection layer, and then forming a hole transport layer on the pixel separate layer configured with the hole injection layer by vacuum evaporation, physical vapor deposition, chemical vapor deposition, pulsed laser deposition, or the like. (2) aligning an open mask with the pixel separate layer, and then forming a light-emitting layer and an electron transport layer in sequence on the pixel separate layer configured with the hole transport layer by vacuum evaporation, physical vapor deposition, chemical vapor deposition, pulsed laser deposition, or the like.

In this manner, the hole transport layer formed by the second fine mask can effectively prevent charge crosstalk of luminous effects from occurring in the hole transport layer of the organic light-emitting device.

In one specific embodiment, sub step B may further include: depositing a hole transport layer, an electron blocking layer, a light-emitting layer, a hole blocking layer, an electron transport layer, and an electron injection layer in sequence on the pixel separate layer configured with the hole injection layer, wherein at least one of the hole transport layer, the electron blocking layer, the light-emitting layer, the hole blocking layer, the electron transport layer, and the electron injection layer is formed by using a second fine mask.

For example, sub step B may specifically include: (1) aligning the second fine mask with the hole injection layer, and then forming the hole transport layer on the pixel separate layer configured with the hole injection layer by vacuum evaporation, physical vapor deposition, chemical vapor deposition, pulsed laser deposition, or the like. (2) aligning the second fine mask with the hole transport layer, and then forming the electron blocking layer on the pixel separate layer configured with the hole transport layer by vacuum evaporation, physical vapor deposition, chemical vapor deposition, pulsed laser deposition, or the like. (3) aligning an open mask with the pixel separate layer, and then forming the light-emitting layer, the hole blocking layer, the electron transport layer, and the electron injection layer in sequence on the pixel separate layer configured with the electron blocking layer by vacuum evaporation, physical vapor deposition, chemical vapor deposition, pulsed laser deposition, or the like.

In this manner, the hole transport layer and the electron blocking layer formed by the second fine mask can effectively prevent charge crosstalk of luminous effects from occurring in the hole transport layer and the electron blocking layer of the organic light-emitting device.

Particularly, the first fine mask and the second fine mask may be the same fine mask or different masks. In addition, when the hole transport layer, the electron blocking layer, the light-emitting layer, the hole blocking layer, the electron transport layer or the electron injection layer is formed by using the second fine mask, each of the layers may be formed by using a different second fine mask. That is, the second fine mask may be a fine mask in specific or a general name of a plurality of different fine masks. In practice, the second fine mask can be selected according to an actual situation.

Further, after sub step B, the method may further include: forming a cathode on the pixel separate layer, wherein the cathode covers the electron injection layer.

The organic light-emitting device may include the anode, the hole injection layer, the hole transport layer, the electron blocking layer, the light-emitting layer, the hole blocking layer, the electron transport layer, the electron injection layer, and the cathode.

Particularly, in practice, the organic light-emitting device may include certain layers of the hole injection layer, the hole transport layer, the electron blocking layer, the light-emitting layer, the hole blocking layer, the electron transport layer, and the electron injection layer. For example, the organic light-emitting device may include the hole injection layer, the hole transport layer, the light-emitting layer, and the electron transport layer. Then, based on such a structure, the organic light-emitting device may further include the electron blocking layer, the hole blocking layer, or the electron injection layer. Furthermore, parameters such as efficiency, lifespans, and viewing angles of the hole transport layer, the electron blocking layer, the light-emitting layer, the hole blocking layer, the electron transport layer, and the electron injection layer can be verified to determine whether there are charge crosstalk effects. When there is charge crosstalk of luminous effects, use fine masks to fabricate corresponding layers of the organic light-emitting devices to avoid the problem that the charge crosstalk of luminous effects occurs in the corresponding layers of the organic light-emitting devices.

Distinct from the prior art, the method of manufacturing the display panel of the embodiment of the present application is implemented to effectively avoid the occurrence of charge crosstalk of luminous effects in a light-emitting device by spacing the hole injection layers of the adjacent organic light-emitting devices, thereby improving luminous efficiency of the light-emitting device and extending service life thereof.

Please refer to FIG. 5. FIG. 5 is a schematic structural view of a display device of an embodiment of the present application. A display device 50 includes a driving circuit and a display panel 51 described in either one of the above-mentioned embodiments, wherein the driving circuit is configured to provide a driving voltage for the display panel.

The display panel includes a substrate, and a pixel separate layer and an organic light-emitting device layer both sequentially disposed on the substrate. The pixel separate layer includes a plurality of dividing bodies and a plurality of open areas spaced apart from each other, wherein adjacent two of the open areas are separated by the dividing bodies, and the organic light-emitting device layer includes a plurality of organic light-emitting devices each including a hole injection layer, and wherein the hole injection layers of adjacent two of the organic light-emitting devices are spaced apart from each other.

Distinct from the prior art, the display device in this embodiment is configured to effectively avoid the occurrence of charge crosstalk of luminous effects in a light-emitting device by spacing the hole injection layers of the adjacent organic light-emitting devices, thereby improving luminous efficiency of the light-emitting device and extending service life thereof.

The above disclosure is only the preferable embodiments of the present application, and is not intended to limit the present application. Any modifications, equivalent substitutions and improvements made within the spirit and principles of the present application should be included in the scope of claims of the present application.

What is claimed is:

1. A display panel, comprising:
a substrate, and a pixel separate layer and an organic light-emitting device layer both sequentially disposed on the substrate;
wherein the pixel separate layer comprises a plurality of dividing bodies and a plurality of open areas spaced apart from each other, wherein adjacent two of the open areas are separated by the dividing bodies, and the organic light-emitting device layer comprises a plurality of organic light-emitting devices each comprising a hole injection layer, and wherein the hole injection layers of adjacent two of the organic light-emitting devices are spaced apart from each other.

2. The display panel of claim 1, wherein each of the organic light-emitting devices further comprises a hole transport layer disposed on the pixel separate layer configured with the hole injection layer, wherein the hole transport layers of adjacent two of the organic light-emitting devices are spaced apart from each other.

3. The display panel of claim 1, wherein each of the organic light-emitting devices further comprises a light-emitting layer disposed on the pixel separate layer configured with the hole injection layer, wherein the light-emitting layers of adjacent two of the organic light-emitting devices are spaced apart from each other.

4. The display panel of claim 1, wherein each of the organic light-emitting devices further comprises an electron transport layer disposed on the pixel separate layer configured with the hole injection layer, wherein the electron transport layers of adjacent two of the organic light-emitting devices are spaced apart from each other.

5. The display panel of claim 1, wherein each of the organic light-emitting devices further comprises an electron blocking layer, a hole blocking layer, and an electron injection layer sequentially disposed away from the hole injection layer, wherein at least one of the electron blocking layers, the hole blocking layers, and the electron injection layers of adjacent two of the organic light-emitting devices are spaced apart from each other.

6. The display panel of claim 1, wherein each of the organic light-emitting devices further comprises an anode disposed on the open area and located between the substrate and the hole injection layer.

7. A method of manufacturing a display panel, comprising:
providing a substrate;
forming a pixel separate layer comprising a plurality of dividing bodies and a plurality of open areas spaced apart from each other, wherein adjacent two of the open areas are separated by the dividing bodies; and
forming an organic light-emitting device layer on the substrate configured with the pixel separate layer, wherein the organic light-emitting device layer comprises a plurality of organic light-emitting devices each comprising a hole injection layer, and wherein the hole injection layers of adjacent two of the organic light-emitting devices are spaced apart from each other.

8. The manufacturing method of claim 7, wherein the forming an organic light-emitting device layer on the substrate configured with the pixel separate layer comprises:
depositing, by using a first fine mask, a hole injection layer on the substrate configured with the pixel separate layer; and
depositing a hole transport layer, a light-emitting layer, and an electron transport layer in sequence on the pixel separate layer configured with the hole injection layer, wherein at least one of the hole transport layer, light-emitting layer, and the electron transport layer is formed by using a second fine mask.

9. The manufacturing method of claim 8, wherein before the depositing, by using a first fine mask, a hole injection layer on the substrate configured with the pixel separate layer, the method further comprises:
evaporating an anode in the open areas.

10. The manufacturing method of claim 8, wherein the depositing a hole transport layer, a light-emitting layer, and an electron transport layer in sequence on the pixel separate layer configured with the hole injection layer comprises:
depositing, by using the second fine mask, the hole transport layer on the pixel separate layer configured with the hole injection layer;
depositing, by using an opening mask, the light-emitting layer and the electron transport layer in sequence on the pixel separate layer configured with the hole transport layer.

11. The manufacturing method of claim 7, wherein each of the organic light-emitting devices further comprises an electron blocking layer, a hole blocking layer, and an electron injection layer sequentially disposed away from the hole injection layer, wherein at least one of the electron blocking layers, the hole blocking layers, and the electron injection layers of adjacent two of the organic light-emitting devices are spaced apart from each other.

12. A display device, comprising a driving circuit and a display panel, wherein the driving circuit is configured to provide a driving voltage for the display panel, and the display panel comprises substrate, and a pixel separate layer and an organic light-emitting device layer both sequentially disposed on the substrate;
wherein the pixel separate layer comprises a plurality of dividing bodies and a plurality of open areas spaced apart from each other, wherein adjacent two of the open areas are separated by the dividing bodies, and the organic light-emitting device layer comprises a plurality of organic light-emitting devices each comprising a hole injection layer, and wherein the hole injection layers of adjacent two of the organic light-emitting devices are spaced apart from each other.

13. The display device of claim 12, wherein each of the organic light-emitting devices further comprises a hole transport layer disposed on the pixel separate layer configured with the hole injection layer, wherein the hole transport layers of adjacent two of the organic light-emitting devices are spaced apart from each other.

14. The display device of claim 12, wherein each of the organic light-emitting devices further comprises a light-emitting layer disposed on the pixel separate layer configured with the hole injection layer, wherein the light-emitting layers of adjacent two of the organic light-emitting devices are spaced apart from each other.

15. The display device of claim 12, wherein each of the organic light-emitting devices further comprises an electron transport layer disposed on the pixel separate layer configured with the hole injection layer, wherein the electron transport layers of adjacent two of the organic light-emitting devices are spaced apart from each other.

16. The display device of claim 12, wherein each of the organic light-emitting devices further comprises an electron blocking layer, a hole blocking layer, and an electron injection layer sequentially disposed away from the hole injection layer, wherein at least one of the electron blocking layers, the hole blocking layers, and the electron injection layers of adjacent two of the organic light-emitting devices are spaced apart from each other.

17. The display device of claim 12, wherein each of the organic light-emitting devices further comprises an anode disposed on the open area and located between the substrate and the hole injection layer.
